(19) United States
(12) Patent Application Publication
(10) Pub. No.: US 2015/0364614 A1
(43) Pub. Date: Dec. 17, 2015

(54) Detector

(71) Applicant: UNIVERSITY OF EXETER, Exeter, Devon (GB)

(72) Inventors: Freddie Withers, Exeter, Devon (GB); Thomas H. Bointon, Exeter, Devon (GB); Monica F. Craciun, Exeter, Devon (GB); Saverio Russo, Exeter, Devon (GB); Steven Martins, Exeter, Devon (GB)

(73) Assignee: University of Exeter, Exeter, Devon (GB)

(21) Appl. No.: 14/761,233

(22) PCT Filed: Jan. 14, 2014
(86) PCT No.: PCT/GB2014/050099

§ 371 Date: Jul. 15, 2015

(30) Foreign Application Priority Data
Jan. 15, 2013 (GB) 1300695.2
Apr. 2, 2013 (GB) 1305897.9

(51) Int. Cl. H01L 31/028; H01L 31/103

(52) U.S. Cl. CPC H01L 31/028; H01L 31/103

(57) ABSTRACT

A detector is described comprising a first graphene element (12), the first graphene element (12) comprising a few layer graphene element functionally doped with a dopant material and to which at least one electrode is connected.

This invention relates to a detector, and in particular to a graphene based detector. The detector may conveniently serve as a photodetector, but is also suitable for use in other applications including in radiation detectors.

Photodetectors are in widespread use, for example in the capture of images in digital still and video cameras, in solar panels, in a range of sensors and in other devices. Harvesting energy from photons is of tremendous importance to society as it may allow a reduction in reliance upon other sources of energy and thereby contribute to a reduction in carbon footprint.

In typical photodetectors or photovoltaic devices, the conversion from photons into electrical voltage is accomplished exploiting the in-built electric field at the interface of a p-doped and n-doped semiconductor to separate the photo-generated electron-hole pairs and originate a forward photovoltage. However, the intrinsic band-gap of standard semiconductors restricts the photoresponsiveness of these devices to specific light band-widths. To harvest electricity over a wide range of the sun light spectrum the multi-junction design of stacked p-n interfaces tuned to different bandwidths has been proposed. Though these solar cells display an improved light harvesting efficiency, they are typically brittle, heavy and therefore difficult to implement in future flexible electronic devices.

Unlike conventional semiconductor materials, pristine single- and few layer-graphene (FLG) materials have no band gap which renders them useful in large band-width photovoltaic applications. Previous optoelectronic studies on graphene devices have shown that the photothermoelectric effect is at the origin of the measured photovoltage in graphene pn-junctions and in single-bilayer interfaces. On the other hand, the photovoltage measured at the graphene-metal interface is due to a built in electric field near the contact as a result of charge transfer from the metal contact to the graphene. These graphene hybrid structures are at the core of a new generation of ultrafast photodetectors with a remarkably high bandwidth (500 GHz), zero source-drain bias (hence zero dark current) operation, and good internal quantum efficiency. However, these devices still employ opaque metallic components or elements which would introduce significant haze when used in smart windows, mirrors and in other optical applications in which optical transparency is of importance.

As with photodetectors, the characteristics of graphene are not fully exploited in other forms of detector.

It is an object of the invention to provide a detector such as a photodetector or a radiation detector in which at least some of the disadvantages associated with known detectors, for example as mentioned hereinbefore, are overcome or are of reduced impact.

According to the present invention there is provided a detector comprising a first graphene element, the first graphene element comprising a few layer graphene (FLG) element functionally doped with a dopant material and to which at least one electrode is connected.

The detector may comprise a photodetector. The photodetector conveniently further comprises a second graphene element adjacent the first graphene element and forming an interface therewith, wherein the second graphene element comprises a pristine graphene element.

The dopant material conveniently comprises FeCl₃. However, other dopants may be used. By way of example, the dopant material could be CuCl₃. Furthermore, other dopant materials including organic molecules such as Rubrene and Pentacene could be used. Indeed other dopants including lithium or potassium or, for example, quantum dots of zinc oxide could be used.

The functionalization of the few layer graphene element using the dopant material may be achieved in any suitable manner. By way of example, functionalization of a few layer graphene element by intercalation with FeCl₃ is described in Khrapach, I.; Withers, F.; Bointon, T. H.; Polyushkin, D. K.; Barnes, W. L.; Russo, S.; Craciun, M. F. Advanced Materials 2012, 24, 2844-2849.

The functionally doped few layer graphene element may include as few as one graphene layer or, depending upon the application in which the photodetector is to be used and whether or not the photodetector must be of transparent form, may include up to, for example, 20 layers. However, where optical transparency is of importance, the number of graphene layers present in each few layer graphene element is preferably fewer than 10 layers. Where the doping is by intercalation as described in the above mentioned paper then the few layer graphene element will include two or more graphene layers as if only a single graphene layer were present the dopant on the surface thereof may tend to migrate with the result that, over time, that graphene element would no longer be appropriately functionally doped.

It will be appreciated that as the photodetector makes use of two graphene elements located one upon the other, rather than a single graphene element used in conjunction with a metal element, the photodetector may be of enhanced optical transparency. Furthermore, the photodetector may be of enhanced flexibility and may be able to be stretched, these characteristics of the graphene elements no longer being constrained by the presence of adjacent metallic elements. The photodetector may be able to be used over an increased range of temperatures compared to a photodetector in which metallic elements are present as graphene remains stable over an increased temperature range.

As with known photodetector devices, the photodetector may be used in a wide range of optical devices or applications including those outlined hereinbefore. In addition, the device may be used in applications in which the optical transparency of the photodetector is of importance. For example, the photodetector could be employed in intelligent window applications, could be incorporated into the lens of a camera or into the lenses of spectacles. It will be appreciated, however, that the invention is not restricted in this regard, and that it may be employed in a number of other applications.

The all graphene photovoltaic devices outlined hereinbefore may be able to harvest energy over the entire sun light spectrum, while offering unique properties such as ultra-lightweight (i.e. graphene is just one atom thick), mechanical flexibility and optical transparency. The leap to all-graphene structures would enable the development of a new generation of transparent photovoltaic devices which do not suffer from haze or in which haze is significantly reduced.

Alternatively, the detector may comprise a radiation detector. In such an arrangement, the dopant conveniently comprises fluorine. Irraditation of such a detector with, for example, β-particles results in breakdown of the bonds between the graphene and the fluorine, and consequently in a reduction in the level of doping of the graphene. Conveniently the graphene element has source and drain electrodes connected thereto. In such an arrangement, upon breakdown of the graphene-fluorine bonds, the source-drain current will increase for a fixed source-drain voltage bias, and the increased current can be used to provide an indication that the detector has been irradiated, and the level of irradiation to which the detector has been exposed.

The invention will further be described, by way of example, with reference to the accompanying drawings, in which:

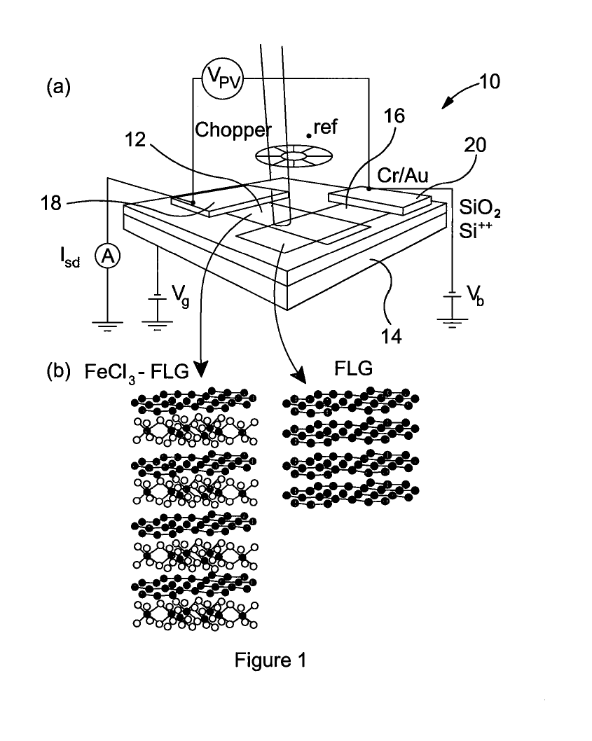

FIG. 1 is a diagrammatic representation of a photodetector in accordance with an embodiment of the invention;

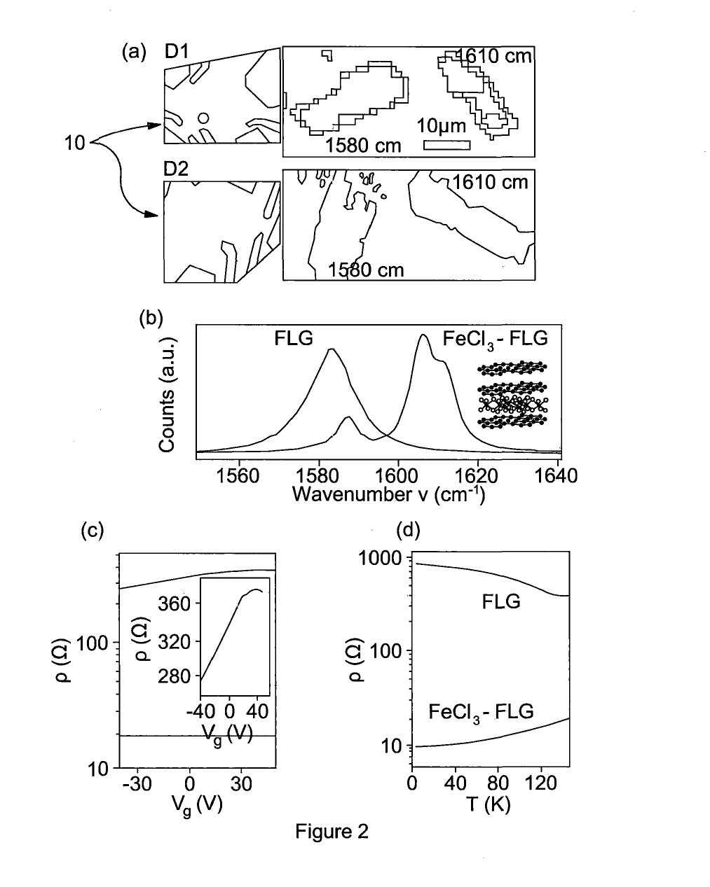

FIGS. 2a, 2b, 2c and 2d are optical microscope images of two example devices, along with photovoltage spectroscopy images of parts thereof, and illustrating the results of tests conducted thereon;

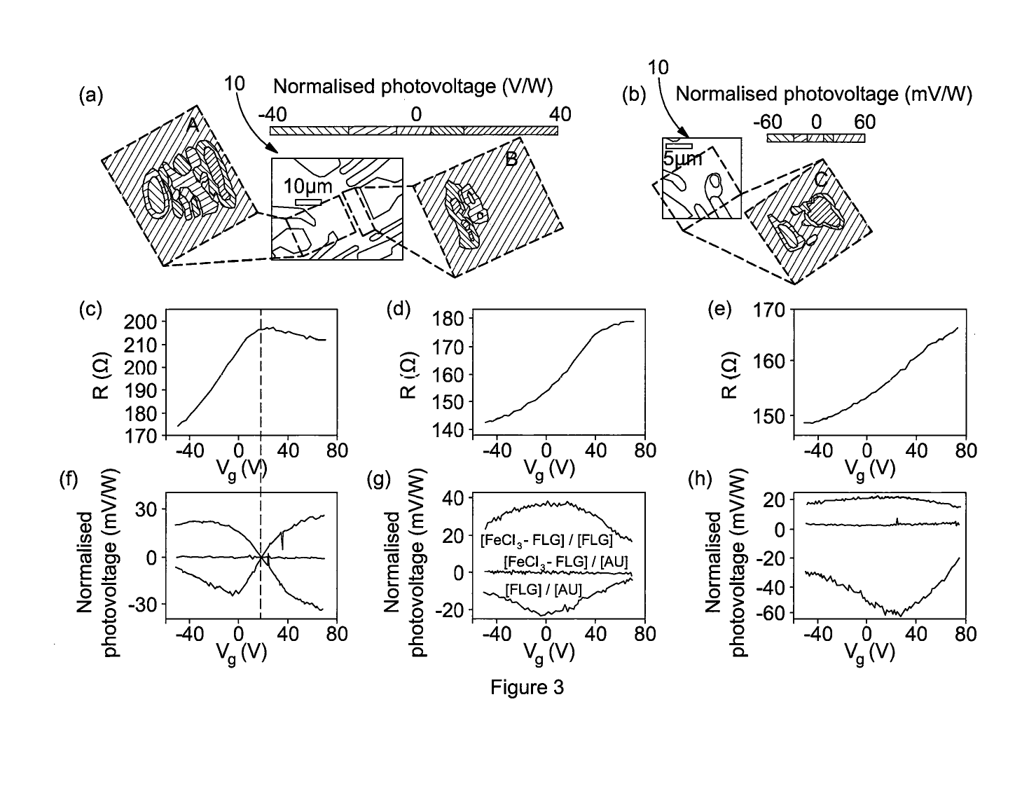

FIGS. 3a to 3h are views illustrating the effect of the exposure of the detector to light;

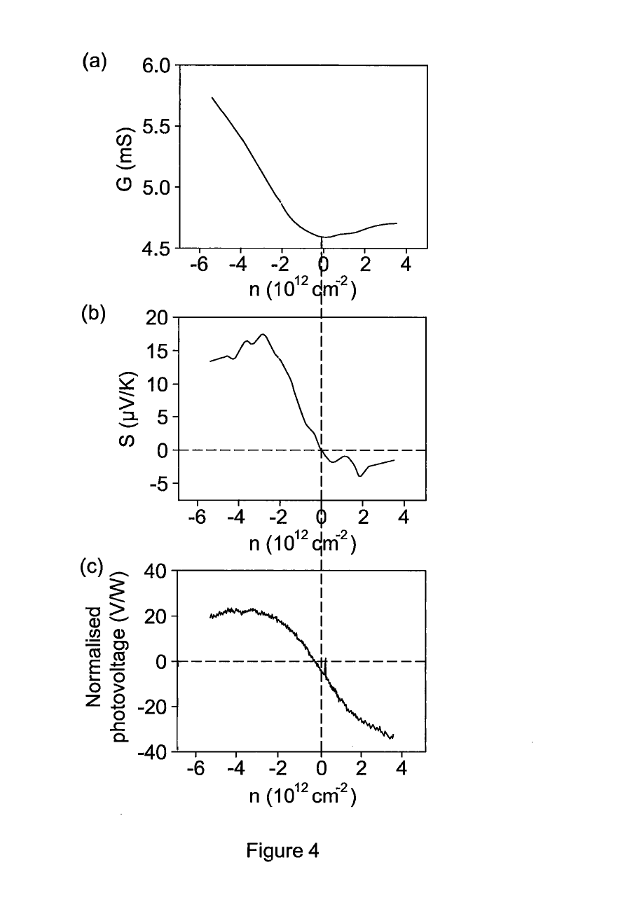

FIGS. 4a to 4c are a series of graphs explaining the photothermoelectric effect;

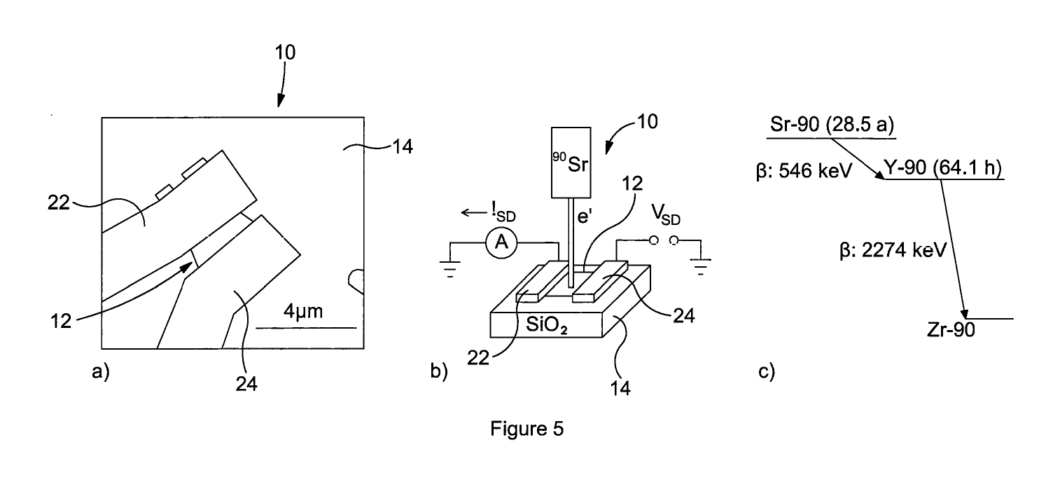

FIGS. 5a to 5c are images relating to a radiation detector in accordance with another embodiment of the invention; and

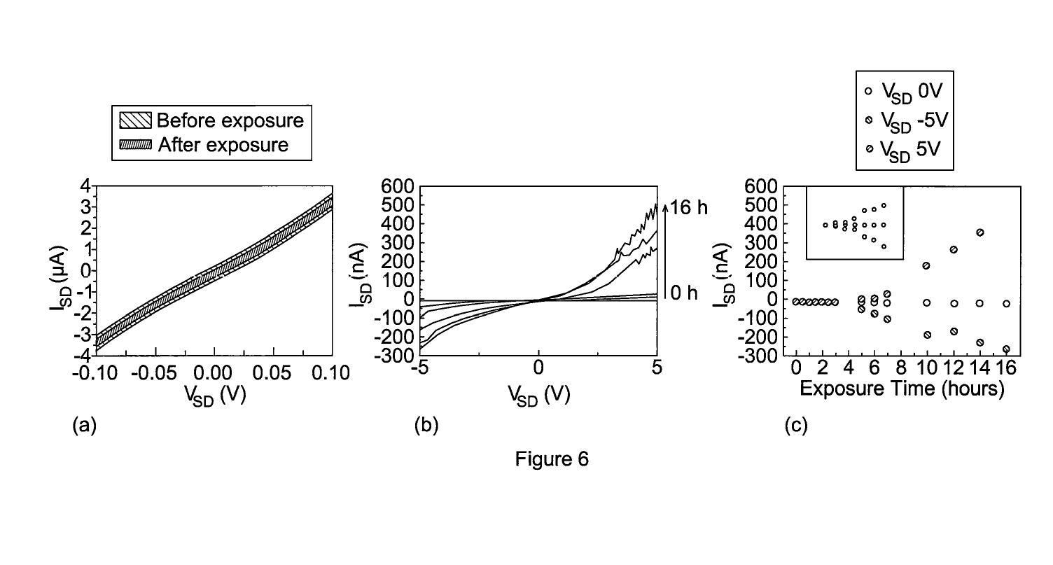

FIGS. 6a to 6c are a series of graphs illustrating the effect of the exposure of the detector to radiation.

Referring firstly to FIG. 1, an all-graphene photodetector device 10 in accordance with an embodiment of the invention is illustrated. The device 10 is based on FeCl₃ intercalated few-layer graphene (FeCl₃-FLG, dubbed graphexeter, a process for the preparation of which is described in the Khrapach et al paper referred to hereinbefore) and pristine graphene. The FeCl₃ intercalation is known to dope graphene to record high charge carrier densities (up to √9×10¹⁴ cm⁻²) and it drops the room temperature square resistance of graphene to just a few Ohms making this material a very good transparent conductor. As will be explained below, at the interface between FeCl₃-FLG/graphene a dominant photovoltage comparable to the signal measured at the graphene/Au interface is observed. A sign reversal of the photovoltage is also observed upon sweeping the chemical potential of the pristine FLG through the charge neutrality point and it has been demonstrated as discussed below that this is due to the photothermoelectric effect.

The device 10 is fabricated by firstly depositing a first few layer graphene element 12 onto heavily doped Si/SiO₂ substrate 14. This may be achieved by the use of a mechanical exfoliation technique. Raman spectroscopy and optical contrast techniques may be used to determine the number of graphene layers in the element 12 as well as their stacking order. Once the first element 12 has been deposited, it is doped by intercalation with FeCl₃. The intercalation process is performed at a temperature of 360° C. degrees and a pressure of 2×10⁻⁴ torr for duration of 7.5 hours following the methodology described in the above referenced Khrapach et al paper. During this process ferric chloride molecules penetrate between the layers of FLG and heavily p-dope it to record high levels of 9×10¹⁴ cm⁻². In this manner, it will be appreciated that the first graphene element 12 is functionally doped.

Subsequently, a pristine FLG flake or element 16 is deposited, for example, by being transferred over the first, FeCl₃-FLG, flake or element 12. This may be achieved using any suitable technique, for example by following the methods described in Dean, C. R.; Young, A. F.; Meric, I.; Lee, C.; Wang, L.; Sorgenfrei, S.; Watanabe, K.; Taniguchi, T.; Kim, P.; Shepard, K. L.; Hone, J. Nature Nanotechnology 2010, 5, 722-726; or Britnell, L.; Gorbachev, R. V.; Jalil, R.; Belle, B. D.; Schedin, F.; Mishchenko, A.; Georgiou, T.; Katsnelson, M. I.; Eaves, L.; Morozov, S. V.; Peres, N. M. R.; Leist, J.; Geim, A. K.; Novoselov, K. S.; Ponomarenko, L. A. Science 2012, 335, 947-950.

After deposition of the elements 12, 16, independent multiple electric contacts 18, 20 are made thereto through the use of Cr/Au (5 nm/70 nm) in the usual way.

The characterization and operation of the device 10 may be assessed using the measurement setup illustrated in FIG. 1. During the testing of the device 10, the first, FeCl₃-FLG flake or element 12 is kept at ground, while a small dc bias of 0.1 mV is applied to the second, pristine FLG flake or element 16. The all-graphene photovoltaic device 10 is then illuminated using a 532 nm HeNe laser focused by using a 100× objective to 1.5 micron spot size at a power of 8.2 μW. The beam is chopped at 370 Hz, and the chopper used as reference to a lock-in amplifier which measures the photovoltage. The heavily doped Si-substrate acts as a global back gate which may be used to tune the chemical potential of graphene, whilst the resistivity of the FeCl₃-FLG flake or element 12 is unaffected by the typical values of used gate voltage due to the high doping level mentioned hereinbefore.

Two devices 10 manufactured using the technique outlined hereinbefore are mounted on a scanning stage which allows mapping or plotting of the photoresponse of these graphene-based heterointerfaces in the x-y directions with a spatial resolution of 1 μm.

To check the homogeneity of the intercalation process Raman spectroscopy is employed. FIG. 2(a) shows a map of the Raman G-band for the non-intercalated and intercalated parts for the two devices 10 labelled D1 and D2. It is apparent that the pristine FLG element 16 shows the well-known strong Raman intensity at 1580 cm⁻¹ corresponding to the G-band, whereas a strong Raman intensity at 1610 cm⁻¹ is present over the whole area of the intercalated FLG element 12 of each device 10 demonstrating the uniformity of the intercalation process.

The upshift of the G-band to 1612 cm⁻¹ and 1625 cm⁻¹ has been previously studied and attributed to charge transfer from FeCl₃ to graphene. More specifically, the shift of the G-band to 1612 cm⁻¹ is a signature of a graphene sheet with only one adjacent FeCl₃ layer, whereas the shift to 1625 cm⁻¹ characterizes a graphene sheet sandwiched between two FeCl₃ layers. Information regarding the structure of the first element 12 can thus be deduced by studying for these shifts. FIG. 2(b) shows the Raman G-band for the pristine (blue) and intercalated FLG of the device (red). The pristine FLG is only very lightly doped as indicated by the Raman G-band appearing at 1583 cm⁻¹. On the other hand, the Raman spectrum of the intercalated FLG shows three shifts of the G-band to 1587, 1608 and 1610 cm⁻¹. These observations suggest that the peak at 1610 cm⁻¹ originates from two graphene layers sandwiching one layer of FeCl₃ whereas the other peaks are due to doped pristine graphene layers. The intercalated flakes or elements 12 which were selected for these tests are trilayer elements, and so the structure can be understood to be a layer of FeCl₃ sandwiched between a graphene monolayer and a graphene bilayer as schematically shown in the inset of FIG. 2(b).

To further characterize the devices 10, the electrical transport properties of the independently contacted pristine FLG and FeCl₃-FLG flakes or elements 12, 16 are studied. Electrical measurements are performed in constant current conditions using an excitation current of 100 nA in 4-terminal configuration to avoid the contact resistance at the interface with metals. A summary of the back-gate and temperature dependence of the resistance for the device D1 is presented in FIGS. 2(c) and (d). The FeCl₃-FLG element 12 shows no gate control of the resistivity (red curve in FIG. 2(c)), which is typical of heavily doped graphene. On the other hand, the pristine FLG element 16 (see blue curve in FIG. 2(c)) exhibits the expected large modulation of resistance as a function of gate voltage and a maximum resistance at V_{G}=40V for this specific device. This indicates the presence of residual p-doping probably caused by FeCl₃ molecules present on the surface of the underlaying FeCl₃-FLG element 12. Consistently, we observe that the FeCl₃-FLG element 12 has a room temperature resistivity of ≈11Ω which decreases upon lowering the temperature down to 9 Ω at 4.2K (see FIG. 2(d)). The observed metallic behaviour of the resistivity is consistent with the heavy p-doping of the system induced by the intercalation with FeCl₃ and it is contrasted by the typical temperature dependence of the pristine-FLG which shows increasing resistivity upon lowering temperature, see FIG. 2(d).

The optoelectronic properties of the all-graphene photodetector devices 10 were then studied. This was achieved by measuring the photovoltage generated across the interface between the second, pristine FLG element 16 and the first, FeCl₃-FLG element 12 while rastering the laser spot over the active device area. FIGS. 3(a) and (b) show the photovoltage generated in the devices D2 and D1 as a function of position of the laser beam. It is apparent that there is a strong photovoltage at the Au/FLG (blue) interface and FLG/FeCl₃-FLG (red) interface while the photovoltage at the FeCl₃-FLG/Au interface is nearly zero.

To understand the origin of the generated photovoltages we fixed the position of the laser beam on a specific location of the interfaces and by changing the back gate voltage we modulated the chemical potential from holes to electrons in the pristine FLG element 16. FIGS. 3(c), 3(d) and 3(e) show the gate dependence of the resistance for the different interfaces found in the devices D2 and D1 as indicated in the graph. In particular, for the pristine flake of device D2 the charge neutrality point (CNP) occurs at 20 V and the crossover from hole transport to electron transport can be studied (see FIGS. 3(c) and 3(f)).

A comparison of the gate dependence of the photovoltage for all interfaces (i.e. FLG/FeCl₃-FLG (red), Au/FLG (blue) and for FeCl₃-FLG/Au (black) see FIGS. 3(f), 3(g) and 3(h)) reveals that the generated photovoltage at the Au/FLG and FLG/FeCl₃-FLG interfaces switches sign when the gate voltage crosses the charge neutrality point (FLG/FeCl₃-FLG (red), Au/FLG (blue) and FeCl₃-FLG/Au (black) in FIGS. 3(f), 3(g) and 3(h)). This large photovoltage is contrasted by the observed zero photovoltage measured at the FeCl₃-FLG/Au interface. Furthermore, we observe that the photovoltage generated at the Au/FLG interface is of comparable magnitude to that measured at the FLG/FeCl₃-FLG interface but it has opposite sign, i.e. negative in the hole-side and positive in the electron-side. Finally, the photovoltage generated at graphene/FeCl₃-FLG is equivalent or larger than what has been previously reported in doubly gated graphene p-n junctions. These observations suggest that FeCl₃-FLG has a workfunction comparable to that of gold, therefore this intercalated graphene-material is a good replacement for metals or local gates in graphene photodetectors. FeCl₃-FLG can replace expensive and opaque metals in photovoltaic architectures making these structures mechanically flexible and transparent.

To better understand the nature of the photovoltages measured in the devices 10, we note that the photovoltage becomes zero for both the FLG/FeCl₃-FLG interface and the FLG/Au interface at the CNP. This observation suggests that the photothermoelectric effect is at the origin of the observed gate dependence of the photovoltage. Indeed, in the devices 10 we do not expect the photovoltaic effect to contribute significantly to the measured signal since we have fabricated the contacts with chromium at the interface which is known to induce only a very small band bending in graphene.

The photovoltage generated by the photothermoelectric effect is

Vpv=(S₂−S₁)ΔT

where Si is the Seebeck coefficient of the different materials and ΔT is the temperature difference. The Mott relation gives,

$$S = - \frac{{π}^{2} {k}_{B}^{2} T}{3 e} \frac{1}{G} \frac{d G}{d n} \frac{d n}{d E} \qquad ( 1 )$$

For device D2 the top layer graphene is ABA tri-layer graphene and we approximate the E_{f} (n) dependence to be that of bi-layer graphene where,

$${E}_{f} = \frac{1}{2} \sqrt{{( 2 {hv}_{F} )}^{2} π n + 2 {γ}_{1}^{2} - 2 {γ}_{1} \sqrt{{( 2 {hv}_{F} )}^{2} π n + {γ}_{1}^{2}}} \qquad ( 2 )$$

Here y₁ is the interlayer coupling strength, which we take to be 0.4 eV. FIG. 4(a) shows the dependence of the electrical conductance (G) as a function of the charge density(n), where n is extracted from Vg using the plane plate capacitor model. FIG. 4(b) shows the calculated Seebeck coefficient using the measured G(n) and equations 1 and 2 above. The measured photovoltage has a similar charge density dependence to the Seebeck coefficient and both signals cross over from positive to negative at the charge neutrality point see FIG. 4(c). This has to be expected when the photothermoelectric effects dominate the measured photovoltage. In these devices only the Seebeck coefficient of the ABA trilayer flake contributes significantly to the photovoltage since the Seebeck coefficient of the FeCl₃-FLG is zero as there is no gate modulation of the resistivity due to the large density of states.

Furthermore, FIGS. 4(b) and 4(c) show that the Seebeck coefficient and the measured photovoltage are not exactly proportional. This discrepancy can be attributed to the local differences in the magnitude of the Seebeck coefficient induced by inhomogeneous doping of the ABA trilayer graphene flake since the photovoltage is a probe of the local density of states.

It will be appreciated from the description hereinbefore that a photodetector comprising an element of few layer graphene in combination with a functionally doped few layer graphene element demonstrates a good photothermoelectric effect when irradiated and thus may be used in a wide range of applications. As the photodetector is of all-graphene form, it will be appreciated that many of the benefits of graphene, such as its inherent strength, flexibility and optical transparency may be used to beneficial effect.

Whilst for the most part the description hereinbefore relates to the use of FeCl₃ doped graphene, it will be appreciated that this is merely an example and that other dopant materials such as CuCl₃, organic molecules including as Rubrene and Pentacene, or lithium, potassium or quantum dots of, for example, zinc oxide may be used, and the dopants may be applied using any suitable technique, provided that the presence of the dopant results in the functionalization of the graphene such that the graphene has a suitably high charge carrier density as outlined hereinbefore.

The detector described hereinbefore is a photodetector. It will be appreciated, however, that the invention is not restricted in this regard and may be applied to other forms of detector. By way of example, FIGS. 5a and 5b illustrate a device 10 manufactured by fluorination of graphite in a F₂ atmosphere at 450° C. using the methodology described in Nanoscale Research Letters 6, 526 (2011) with a fluorination coverage of 28% (CF_{0.28}). Thin flakes of the fluorinated graphite are then mechanically exfoliated, forming functionally doped graphene elements 12, and are applied to a SiO₂ substrate 14. Source and drain electrodes 22, 24 are applied, contacting to the fluororine doped graphene element 12. The electrodes 22, 24 and graphene element 12 take the configuration of a transistor as shown in FIG. 5a.

In order to test that the device 10 operates as a radiation detector, the device 10 was placed in a vacuum chamber and the pressure thereof reduced to 10⁻³ Torr. A radiation source in the form of a strontium 90 source was placed 5 mm away from the device 10 such that the incident beam of particles was perpendicular to the surface of the graphene element 12 as shown in FIG. 5b. The ⁹⁰Sr source has an activity of 74 kBq and the β particles have an energy of 2274 keV, as illustrated in FIG. 5c. This is much larger than the energy (5.3 eV) required to desorb one fluorene molecule from the graphene surface.

The source-drain current of the device 10 was measured before exposure and at several intervals during exposure. As a control, FIG. 6a is a plot of the current versus voltage characteristics (I-V) of pristine graphene before and after irradiation. It is apparent that no observable change of the resistance of the sample is induced by the radiation. FIG. 6b shows the time evolution of the I-V curves for a fluorine doped graphene device 10 under continuous exposure. Initially the device 10 is completely insulating but after a short time a noticeable source drain current I_{SD} is measured. After 5 hours for a 5 V bias I_{SD} is around 20 nA but by 10 hours this increases by an order of magnitude to around 200 nA. A similar behaviour is seen in other devices. The I-V of the fluorographene transistor changes irreversibly upon exposure of these transistors to radiation, suggesting that the CF bonds have been broken lowering the overall fluorination coverage of the graphene. A summary plot showing the evolution of the measured current for fixed source-drain bias upon irradiation is shown in FIG. 6c.

It is clear that the device 10 incorporating the fluorine doped graphene element 12 can be used to output a signal indicative of the level of radiation to which the element 12 has been exposed.

In the description hereinbefore reference is made to the use of exfoliation techniques in the formation of the graphene elements. It will be appreciated that the invention is not restricted in this regard and that other fabrication techniques may be used. By way of example, the graphene elements may be deposited using a printing technique similar to ink jet printing, using a graphite material in the ink.

A number of other modifications and alterations may be made to the arrangement described hereinbefore without departing from the scope of the invention as defined by the appended claims.

1. A detector comprising a first graphene element, the first graphene element comprising a few layer graphene element functionally doped with a dopant material and to which at least one electrode is connected.

2. A detector according to claim 1, Wherein the detector is a photodetector.

3. A detector according to claim 2, further comprising a second graphene element adjacent the first graphene element and forming an interface therewith, wherein the second graphene elements comprises a pristine graphene element.

4. A detector according to claim 3, wherein the dopant material comprises FeCl₃.

5. A detector according to claim 4, wherein the dopant material is intercalated into or between the layers of the graphene element.

6. A detector according to claim 3, wherein the dopant material comprises one of CuCl₃, organic molecules, Rubrene or Pentacene, or lithium, potassium or quantum dots of zinc oxide or the like.

7. A detector according to claim 3, wherein the functionally doped few layer graphene element includes as few as one graphene layer.

8. A detector according to claim 3, wherein the functionally doped few layer graphene element includes at least two graphene layers.

9. A detector according to claim 3, wherein the functionally doped graphene element includes up to 20 layers.

10. A detector according to claim 2, and adapted to serve as one of a photovoltaic panel, a sensor, an intelligent window, and a camera or spectacles lens.

11. A detector according to claim 1, wherein the detector is a radiation detector.

12. A detector according to claim 11, wherein the dopant material comprises fluorine.

13. A detector according to claim 11, wherein a source electrode and a drain electrode are connected to the first graphene element.
